(19) United States
(12) Patent Application Publication
(10) Pub. No.: US 2015/0021632 A1
(43) Pub. Date: Jan. 22, 2015

(54) LED WITH MULTIPLE BONDING METHODS ON FLEXIBLE TRANSPARENT SUBSTRATE

(71) Applicant: Heilux, LLC, Eden Prairie, MN (US)

(72) Inventors: Ehssan Taghizadeh, Eden Prairie, MN (US); Aaron J. Golle, Shakopee, MN (US); Walter J. Paciorek, Phoenix, AZ (US); Lee D. Stagni, Plymouth, MN (US)

(73) Assignee: Heilux, LLC, Eden Prairie, MN (US)

(21) Appl. No.: 14/209,714

(22) Filed: Mar. 13, 2014

Related U.S. Application Data
(60) Provisional application No. 61/783,919, filed on Mar. 14, 2013.

(51) Int. Cl. H01L 25/13; H01L 33/54; H01L 33/62

(52) U.S. Cl. CPC H01L 25/13; H01L 33/62; H01L 33/54
USPC 257/88

(57) ABSTRACT

Inventive aspects disclosed herein include a flexible device. The flexible device includes a flexible transparent substrate and an adhesive adhered to the flexible transparent substrate, covering a portion of the substrate. The device also includes two or more bare LED dies adhered to the adhesive, the two or more LED dies spaced as little as 0.22 inches (5.4 mm), or less, apart. The device additionally includes a pair of conductive traces on or in the substrate and positioned on opposing sides of the bare LED dies; a pair of conductive pads positioned on opposing surfaces of the bare LED die; and an interconnect that interconnects the pads and the traces.

### PRIORITY APPLICATION

This application claims the benefit of priority to U.S. Application Ser. No. 61/783,919, filed Mar. 14, 2013, which is incorporated herein by reference in its entirety.

### FIELD

Inventive embodiments disclosed herein related to bare (unpackaged) die) LED devices having a transparent flexible substrate and multiple bonding methods to the transparent flexible substrate.

### BACKGROUND

Solid state lighting is advantageous because it significantly lowers energy consumption. Light emitting diode, LED, technology is very efficient in converting electrical energy into light. LEDs are a substantial improvement over traditional light sources. For instance, LEDs do not emit ultra-violet light which is harmful to humans. LEDs have a much longer lifetime compared to other light sources. The lifetime of LEDs may exceed 50,000 hours. LEDs are small in size and are point light sources that offer design flexibility. Current Packaged LED assemblies include a bare LED die, attached and wire bonded to a leadframe. This assembly is encapsulated in an epoxy or silicone resin. A lens is frequently formed using the resin to direct the light out of the package. The typical packaged LED can have 10 to 15 separate components. Packaged LEDs need to be mounted onto the circuit and connected using solder. Frequently a heatsink is needed to form a complete emitter.

### SUMMARY

Inventive aspects disclosed herein include a flexible device, including a flexible transparent substrate; an adhesive adhered to the substrate, covering a portion of the substrate; two or more bare (unpackaged) die LEDs adhered to the adhesive; a pair of flexible conductive traces adhered or etched into the substrate and positioned on apposing sides of the two or more bare LED dies; a pair of conductive pads adhered or etched into the bare LED die and positioned on opposing surfaces of the bare LED die; and a pair of wire interconnections, each wire interconnection bonded to a trace and a pad. The two or more bare LED dies are spaced at a distance as short as 0.22 inches (5.4 mm), or less.

Another flexible device embodiment includes a flexible transparent substrate; and an adhesive adhered to the flexible transparent substrate, covering a portion of the substrate. The flexible device also includes two or more bare LED dies adhered to the adhesive, the two or more LED dies spaced as little as 0.22 inches (5.4 mm), or less, apart. The flexible device additionally includes a pair of conductive traces comprising copper etched or conductive traces adhered into the substrate and positioned on opposing sides of the bare LED die. The device also includes a pair of conductive pads comprising conductive print adhered to the bare LED die and positioned on apposing surfaces of the bare LED die; and conductive print interconnecting the each member of the pair of traces to each member of the pair of pads.

Another embodiment includes a flexible transparent device. The flexible transparent device includes a flexible transparent substrate. An adhesive adheres to the flexible transparent substrate, covering a portion of the substrate. Two or more bare LED dies adhered to the adhesive, the two or more bare LED dies spaced as little as 0.22 inches (5.4 mm), or less, apart. The device also includes an interconnect that includes an isotropic conductive material having elements that have been aligned magnetically.

Inventive aspects disclosed herein also include a flexible device. The flexible device includes a flexible transparent substrate and an adhesive adhered to the flexible transparent substrate, covering a portion of the substrate. The device also includes two more bare LED dies adhered to the adhesive, the two or more bare dies spaced as little as 0.22 inches (5.4 mm), or less, apart. The device additionally includes a pair of conductive traces on or in the substrate and positioned on opposing sides of the bare LED dies; a pair of conductive pads positioned on opposing surfaces of the bare LED die; and one or more interconnects that interconnect the pads and the traces.

### DESCRIPTION OF DRAWINGS

FIG. 1 is a cross-sectional view of a flexible bare die LED circuit with devices 10 and 10′ on a flexible substrate employing a wire interconnect.

FIG. 2 is cross-sectional view of a flexible bare die LED device having a round GLOB top,

FIG. 3 is a cross sectional view of a flexible bare die LED device having a flat GLOB top.

FIG. 4 is a cross-sectional view of a flexible bare die LED device having an interconnect comprising a straight wire bond.

FIG. 5 is a cross-sectional view of a flexible bare die LED device having an interconnect comprising a coiled wire bond.

FIG. 6 is a top plan view of one embodiment of a pair of conductive traces on a substrate.

FIG. 7 is a cross-sectional view of one embodiment of a pair of traces and the substrate on which they are etched.

FIG. 8 is a cross-sectional view of one embodiment of a flexible transparent bare die LED circuit with devices 50 and 50′ on a flexible substrate employing a conductive, printed interconnect.

FIG. 9 is a cross-sectional view of a flexible transparent bare die LED device having a round GLOB top and printed interconnect.

FIG. 10 is a cross sectional view of a flexible transparent LED device having a flat GLOB top and printed interconnect.

FIG. 11 is a cross sectional view of one flexible transparent bare die LED device having an anisotropic interconnect.

FIG. 12 is a cross sectional view of another flexible bare die LED device having an anisotropic interconnect.

FIG. 13 is a graphical view that illustrates the temperature rise of an Epistar ES-GEBLV10S as a function of current for the LED configuration disclosed herein in free air.

FIG. 14 is a schematic view that illustrates standard thermal resistance model as described in “Noribachi LED Heat Sink Analysis.

FIG. 15 is a graphical view for a bare chip on PET with no phosphor. Top curve is the rise in the junction temperature and the bottom is the rise on the bottom of the PET.

FIG. 16 is a graphical view showing temperature rise for a square cooling area that is 2.7 mm on a side. The junction temperature is the top curve. The outside of the PET is the bottom one.

FIG. 17 is a graphical view showing calculations for a chip covered with a layer of phosphor. The square cooling area with side a=2.7 mm (same as above).

### DETAILED DESCRIPTION

Technology disclosed herein eliminates most of the packaging components used in a standard packaged LED. The bare die is attached to a flexible transparent substrate which acts as the circuit and heat spreader. An inventive LED emitter, disclosed herein includes only four or five components substrate/circuit, bare die, adhesive, interconnect, and (optionally) phosphor.

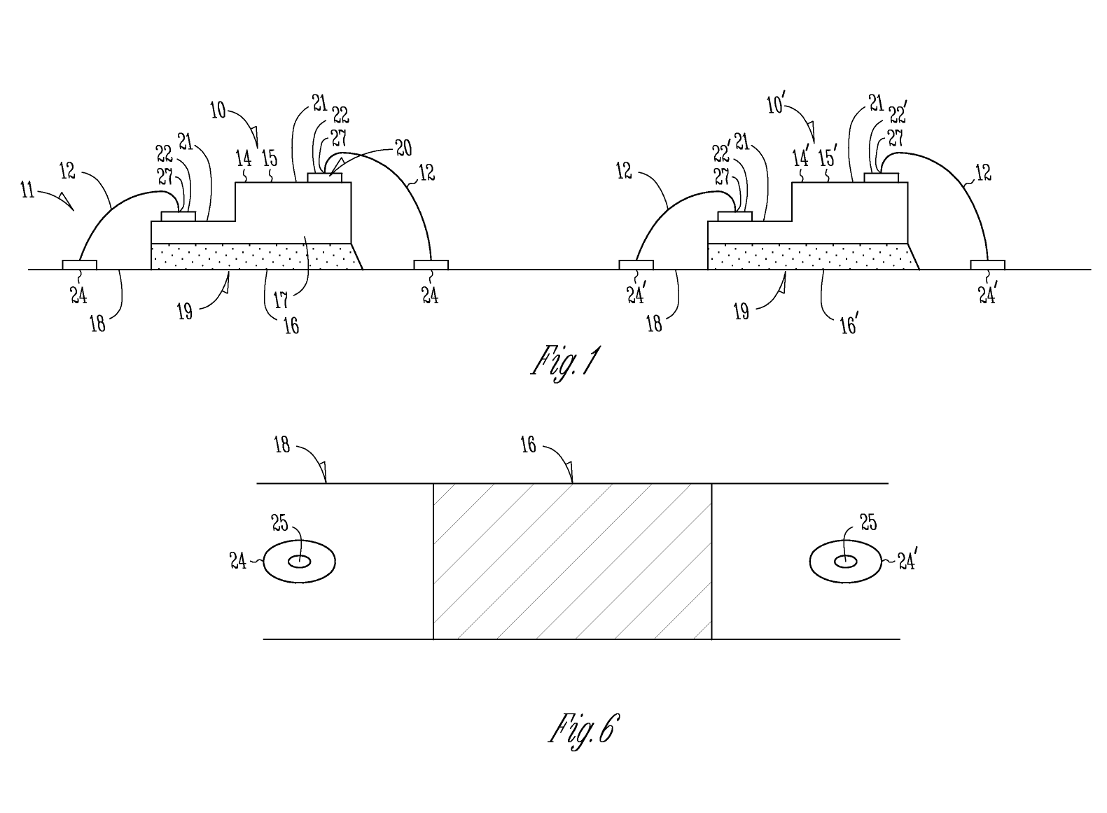

One transparent flexible strip circuit embodiment of the invention disclosed herein, illustrated generally at 11 in FIG. 1 includes bare die LED units 10 and 10′, each having a bare die light emitting diode 14 and 14′affixed to a flexible transparent substrate 18 with an adhesive 16 and 16′. The bare die LED units 14 and 14′, for some embodiments, emit light from a top surface 15 and 15′ of the bare LED die 14 and 14′ as well as a bottom transparent surface 19 of the transparent flexible strip circuit 11. Each bare die on the transparent flexible circuit 11 includes a contact, such as a P-contact 20 and an N-contact 21. The polarity of the contacts is reversible, so that the contact at 20 is of the N-type. The bare die LED units 10 and 10′ of the circuit 11 share the common flexible, transparent substrate 18.

Wire bonds 12 interconnect each of the bare die LEDs 14 and 14′ to the flexible transparent substrate 18 at conductive pads 22 and 22′ on the bare die LED units 10 and 10′ and flexible conductive traces 24 and 24′, respectively, on or within the flexible transparent substrate 18. The two or more bare die LED units 10 and 10′ are spaced a distance that is effective for optimal thermal management. It has surprisingly been found that this distance may be as short as 0.22 inches (5.4 mm) apart, or less, depending upon the type of materials employed to make the substrate and die structure.

The terms, “interconnect or interconnects or interconnections” as used herein, refer to a wire bond or a conductive print or a magnetically aligned anisotropic conductive material (MACM) effective for bonding a bare die LED to a flexible transparent substrate. The wire interconnect embodiments conductively interconnect a conductive pad of a bare die LED to a conductive trace of a substrate. The conductive print interconnect embodiments interconnect a conductive pad of a bare die LED to a conductive trace of a substrate. The MACM embodiments interconnect a conductive pad of a bare die LED to a conductive trace of a substrate.

The flexible transparent substrate enables strip circuit embodiments to provide illumination from dual sides due to the symmetry of the flexible substrate 18 and the transparency of the flexible substrate. The feature of providing illumination from dual sides is due to light from the bare die LED units passing through the substrate 18. This feature of light passing through opposing sides of the substrate 18 significantly increases the efficiency of the circuit 11. Also, the transparent, flexible substrate 18 reduces the number of materials required and the cost, compared to conventional packaged LED units.

While a flexible transparent strip circuit 11 is disclosed, it is understood that flexible, transparent device embodiments also include symmetries other than a strip such as transparent, flexible circles, triangles, squares, symmetries for clothing, symmetries for application to surfaces having curvature as well as flat surfaces, and surfaces that are rollable.

For some embodiments, flexible transparent strips are formed into a twisted “U” shape. For some embodiments, the flexible transparent strip includes a circuit on one surface. For other embodiments, the strip includes a circuit on more than one surface. The flexible transparent strip may be twisted to have LED units directed in a plurality of directions. Because of the flexible transparent substrate 18 light form, the LED units illuminate a volume omnidirectionally, with a substantially similar intensity.

The flexible transparent substrate 18 enables the bare die LED unit 10 or 10′ to move in conformance to different shapes of the transparent flexible strip 11, such as a helical shape. While a flexible strip is described herein, it is understood that the bare die LED units 10 and 10′ also move when adhered to other substrate symmetries.

In addition to flexibility, the transparent strip circuit 11 has a capacity for accommodating component addition. Circuit embodiments disclosed herein that include transparent, flexible substrates are scalable.

For some embodiments, the flexible transparent substrate 18 is organic and includes one or more materials such as polyethylene naphthalate, poly(ethylene-2,6-naphthalene dicarboxylate, CAS No. 25853-85-4, hereinafter, PEN; polyethylene terephthalate, hereinafter, PET; a thin, transparent glass, PVC, flexible polycarbonate, phenolic, acrylic, flexible metal and flexible ceramic. Other flexible polymers, organic-inorganic hybrids and metal foils may also be used. For some embodiments, PEN and PET substrates include a flexible coating to minimize surface defects. For some embodiments, polymer-based substrates such as PEN and PET are heat stabilized in order to reduce shrinkage and their coefficients of thermal expansion.

For some embodiments, the pads 22 and 22′ and bare die LED units 14 and 14′ positioned on the flexible transparent substrate 18 are also flexible. For these embodiments, the bare die LED units are sufficiently thin that they display a degree of flexibility,

The bare die LED units 10 and 10′ positioned on transparent flexible strip 11, each include interconnect wires 12 securely bonded, with at least a flexible trace 24 to the flexible substrate 18 and to an upper surface 21, at a conductive pad 22 of each of the bare die LED units 14. The wires 12 electrically interconnect the bare die LED units 10 and 10′ to the substrate 18. The wires 12 terminate at ends 25 that are, for some embodiments, pressed down on etched copper contact metal at each of the traces 24 in a manner effective for securing each of the wire ends 25 to the conductive, contact metal forming the trace 24. The wire bonds 25 are adhered to each of the conductive traces 24 that are for some embodiments, printed onto the flexible substrate 18 by use of one or more of thermosonic energy, ultrasonic energy, and thermocompression. For some embodiments, intermediate bond traces, which are not shown, are designed into the substrate 18 in order to avoid micro-cracking. For some embodiments, the wires 12 terminate at ends 27 that are pressed down on a conductive, contact metal at each of the pads 22.

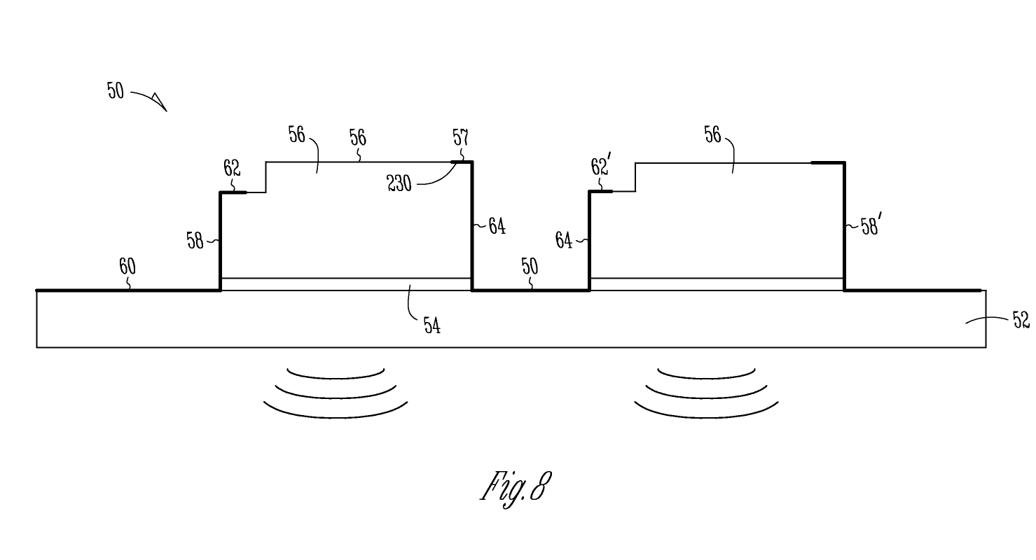

It has surprisingly been found that one or more conductive materials printed onto the trace 24 or 24′ is effective in bonding to ends 25 of wire 12 while also having flexibility compatible with the flexible transparent substrate 18. Bonded traces 24 and 24′ are positioned to create the shortest bond wire possible. One top plan view of traces 24 and 24′ is illustrated in FIG. 6. For some embodiments, substrate bonded traces 24 are gold-plated to a minimum thickness of 0.76 microns. Some bonded trace embodiments employ flash gold printed with A1.

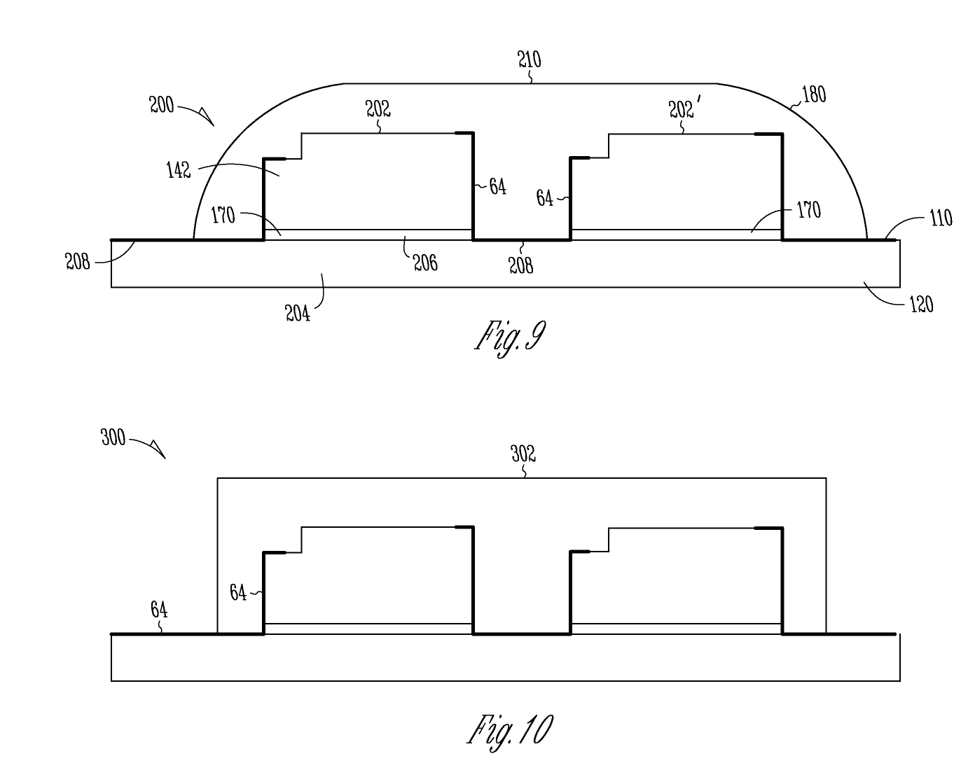

Some bonded traces employ wedge bonding, provided that the wedge bonding produces a bonded trace having flexibility compatible with the flexibility of the substrate 18. Aluminum wire is typically used in wedge bonding. Ball bonding is another usable bonding type provided the bond does not impede the flexibility of the substrate 18. For ball bonding, pads 22 and 22′ are connected onto a die 14 or 14′ with very fine diameter wire. Bonding wire is typically gold having a purity of 99.99%. One cross sectional view of traces 24 and 24 is illustrated in FIG. 7.

The particular wire interconnect employed in the wire bonds depends upon desired wire bond pitch, and current carrying capacity. One type of metal employed is gold wire having a resistance of 1.17 micro-ohms per mil of length and a burn-out current of about 0.7 Amps at a diameter of one mil.

The bare die LED unit 10 or 10′ is adhered to the substrate 18 by the adhesive 16 applied to the substrate 18 in order to bond the bare die LED 14 to the flexible transparent substrate 18. Examples of typical suitable adhesives include EPO-TEK epoxy adhesive solution family like OG-116-31, OG198-55, and OG 142.

It has surprisingly been found that acceptable heat equilibrium is maintained over circuit embodiments without supplementary heat sinking, by distributing the bare die LED units 56 and 56,′ to have a separation that is as little as 5.4 mm (0.02.2 inches), or less. In one embodiment, a typical construction that includes 50 microns (2 mil) PET (polyethylene tereplithalate) transparent flexible substrate and typical bare die blue LEDs with a footprint equivalent to a 0.39 mm square operating at approximately 60 mW, had a separation of 5.4 mm. It should be understood that the minimum separation will vary with the chemical composition and the thickness of the transparent substrate and the power and efficiency of the bare die LEDs. While 5.4 mm is disclosed herein, it is understood that any distance that optimizes thermal distribution and prevents thermal feedback is suitable for use in the inventive embodiments disclosed herein. Power to the bare die LEDs can be in the 45 to 65 mW range. At a nominal 100 lm/W for a typical white LED, this yields 4.5 to 6.5 lumens per LED.

LED embodiments disclosed herein address two factors that impact the dissipation of waste heat generated by the diode the amount of heat generated and highly concentrated power.

One consideration is under-driving the chip. Experiments show that there is an increase in the luminous efficacy when a chip driven at lower currents. A constant luminous output can be achieved using more chips with less total power. This means there is less heat to be dissipated and the heat is less concentrated.

A second advantage is seen when the heat is less concentrated. This advantage can be seen when the characteristics of the LED embodiments herein are compared a calculated model for the heat dissipation.

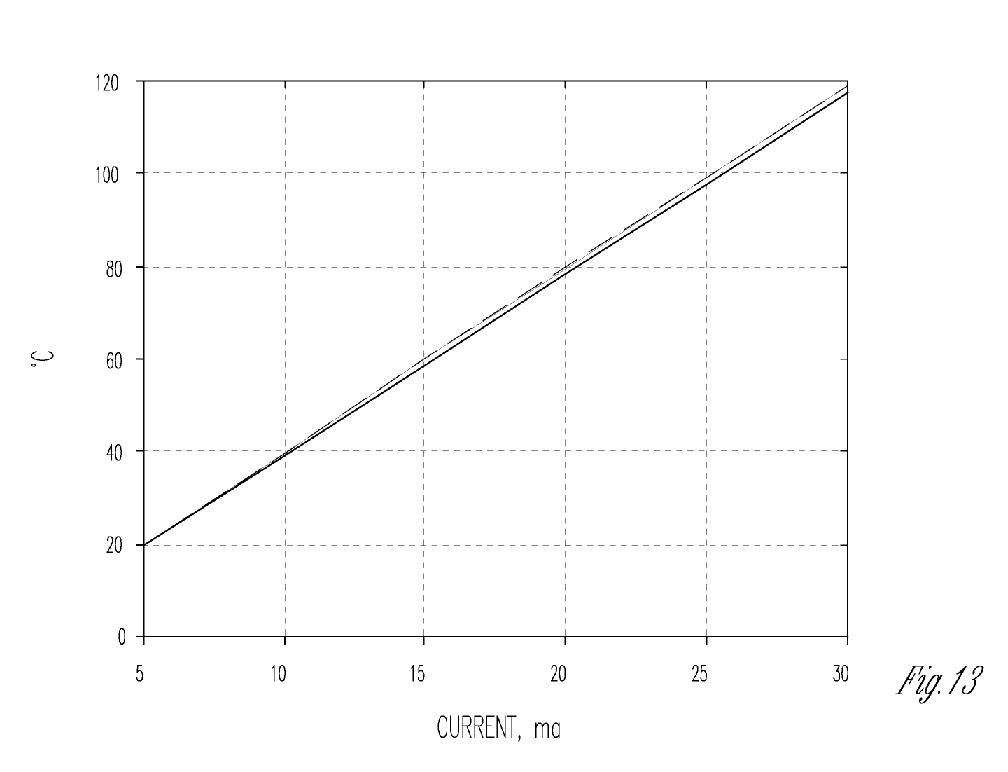

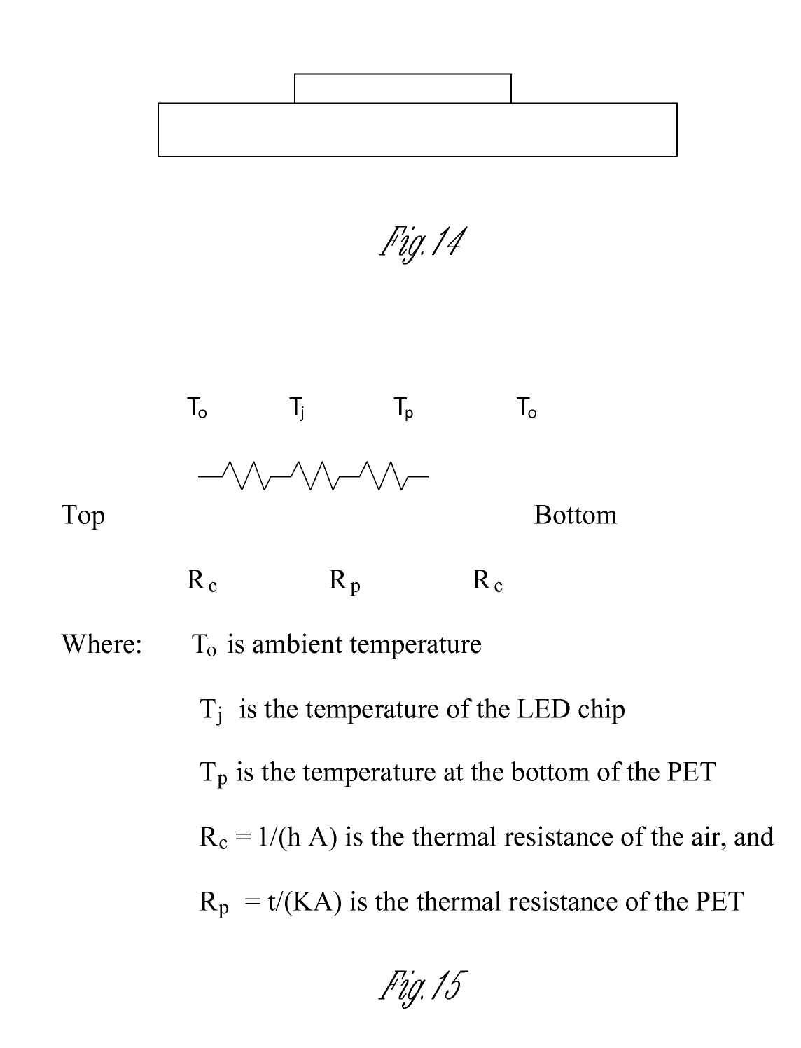

The chart shown in FIG. 13 illustrates the temperature rise of an Epistar ES-CEBLV10S as a function of current for the LED configuration disclosed herein in free air. A micro-thermocouple in intimate thermal contact with the surface of the LED was used to record the equilibrium temperature at an ambient temperature of 17° C. The maximum junction temperature recommended for this LED is 115° C. Assuming the die temperature and the junction temperature are the same at equilibrium, acceptable temperature rises were found in the 15 to 20 mA expected operating range.

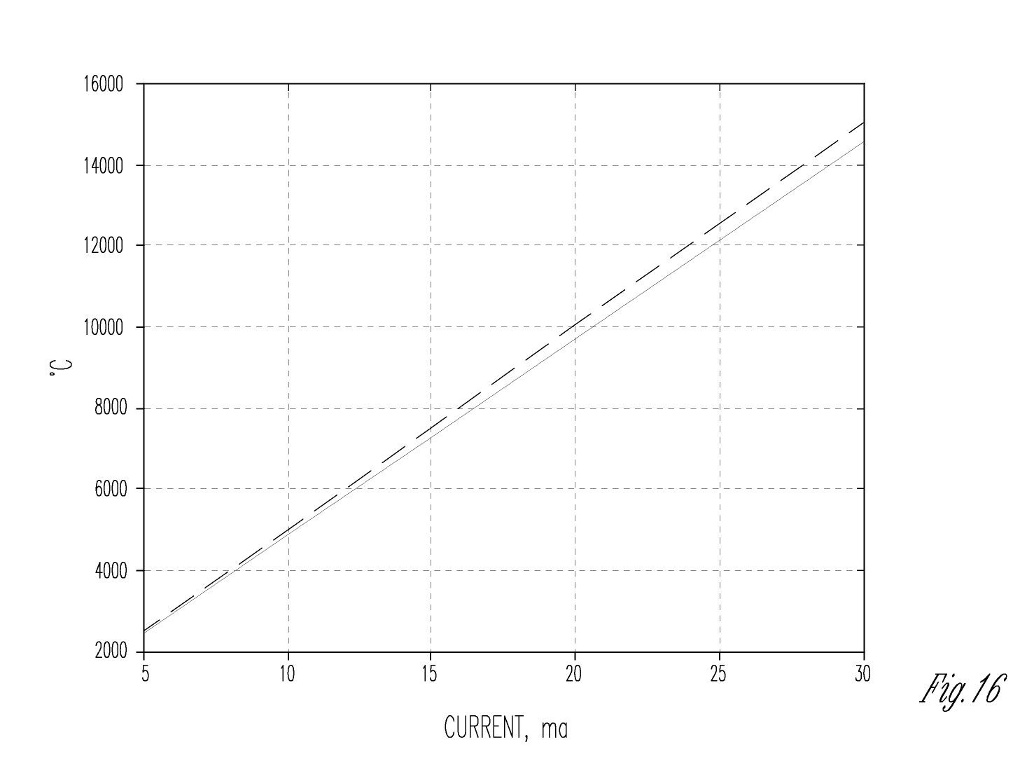

These experimental results can be compared to a standard thermal resistance model as described in “Noribachi LED Heat Sink Analysis.” In the LuinaFlex design a bare LED chip is attached to a flexible substrate. The model is shown in FIG. 14 with a simple schematic and the resulting thermal resistance model.

The heat transfer coefficient for air, h=(Kₐᵢᵣ/L) Nu, where Kₐᵢᵣ is the thermal conductivity of air, 0.026 W/(m ° C.). The parameter, L=A/P, where A is the area being cooled and P is the perimeter of that area. The parameter K is the thermal conductivity of PET and equals 0.2 W/(m ° C.). Nu is the Nusselt number which is the ratio of the convective heat transfer coefficient to the conductive heat transfer coefficient. For free convection from a horizontal fiat plate Nu=0.571 Ra ¼. Ra is the Raleigh number which is found from

Ra=(ΔT/T)[g L³/(vk)] Pr where,

T is the absolute temperature, K

ΔT is the temperature difference

g is the acceleration of gravity, 9.8 m/s²

v is the viscosity of air, 1.5×10⁻⁵ m²/s

k is the thermal diffusivity of air, 1.9×10⁻⁵ m/s, and

Pr is the Prandtl number for air, 0.725

Based on the equations above, the heat transfer coefficient, h, depends strongly on the dimensions of the cooling surface, and, to a lesser degree, the absolute temperature and the temperature gradient. The values calculated in this study were calculated for T=293 K and ΔT=70 K°.

The heat produced in the chip, Q_{dot}, equals a fraction of the power supplied, P=1V where I is the current and V the forward voltage. For an efficient LED this fraction is about 40%. That assumes that 60% of the power is emitted as light. This heat is transferred from the top, Q_{dot}_{_{—}}ₜₒₚ, and from the bottom, Q_{dot}_{_{—}}_{bottom} of the device. From the top.

Q_{dot}_{_{—}}ₜₒₚ=(Tⱼ−Tₒ)/R_{c} (1)

Rearranging gives Tⱼ=Tₒ+Q_{dot}_{_{—}}ₜₒₚ R_{c}. On the bottom the heat flows through the PET and then into the air,

Q_{dot}_{_{—}}_{bottom} −(Tⱼ−Tₚ)/Rₚ (2)

The heat dissipated from the bottom is

Q_{dot}_{_{—}}_{bottom}=(Tₚ−Tₒ)/R_{c} (3)

Solving (3) for Tₚ and substituting into (2) and rearranging gives a second expression for Tⱼ. Setting these expressions equal to each other since the chip is expected to be at a uniform temperature gives a relation relating Q_{dot}_{_{—}}ₜₒₚ and Q_{dot}_{_{—}}_{bottom}. Using Q_{dot}=Q_{dot}_{_{—}}ₜₒₚ+Q_{dot}_{_{—}}_{bottom} we get

Q_{dot}_{_{—}}_{bottom}=Q_{dot}(R_{c})/(2 R_{c}+Rₚ) (4)

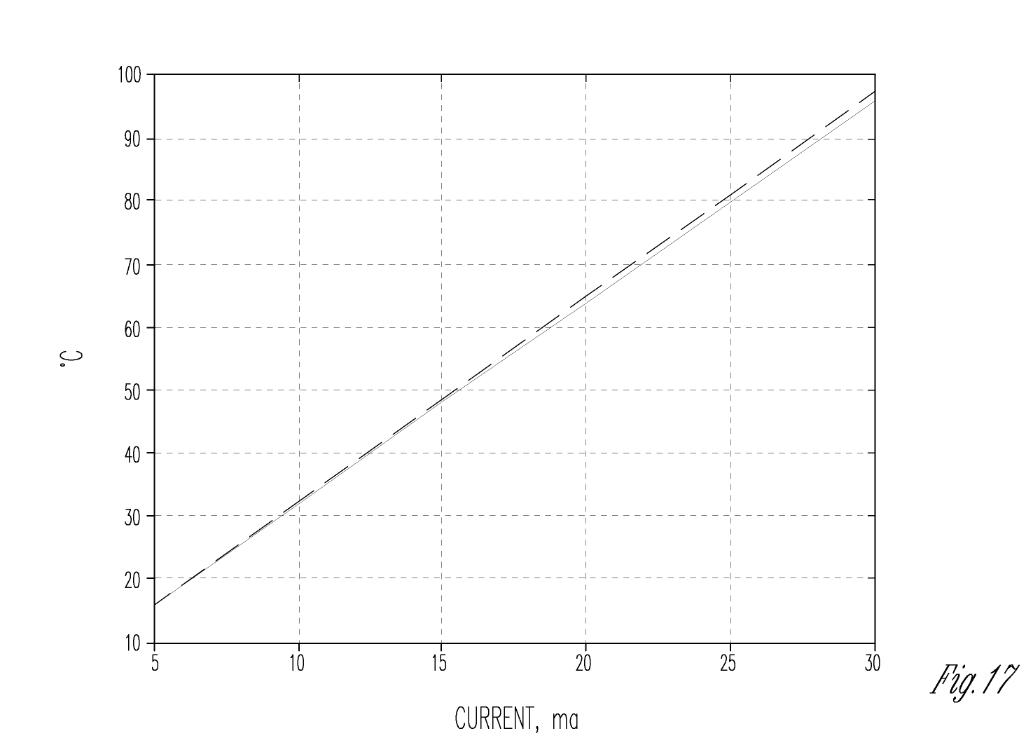

We can now calculate the heat flow from the bottom and the top and the temperatures at each point. The area of the chip is 1.52×10⁻⁷ m2 which would be a square that is 3.9×10⁻⁴ m on a side. Using these values the junction temperature, Tⱼ, and the PET surface temperature, Tₚ, are calculated and shown below. The top curve is the junction temperatue, Tⱼ, and the bottom one is the outside temperature of the PET, Tₚ. A graphical view of calculations for a bare chip on PET with no phosphor are illustrated in FIG. 15. The top cove shows a rose: in the junction temperature and the bottom shows a rise on the bottom of the PET.

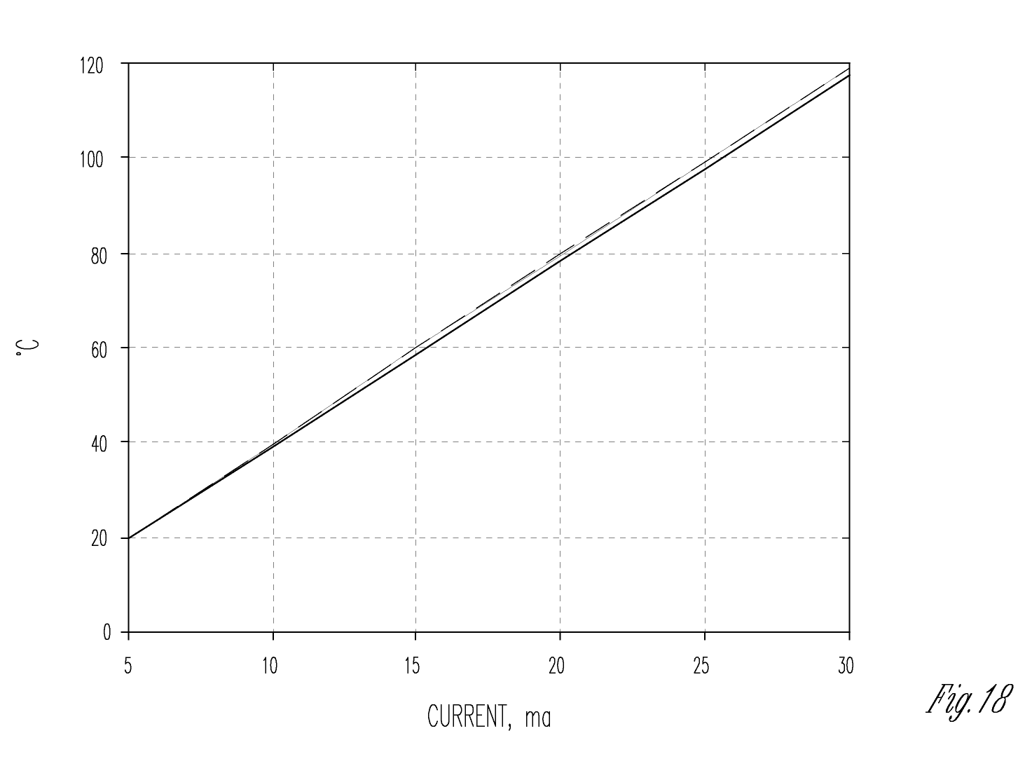

The calculation shows that the chip would be destroyed and the PET would melt. This melting is not seen experimentally and so there must be a more efficient heat flow process. In the above calculation we have assumed that the chip has a nearly uniform temperature because the thermal conductivity of the chip is much higher than YET and air. Now I would like to assume that the thermal conductivity of the PET is much higher than air and so a larger area of the PET would heat before a steady state would be reached. If we assume the measurement of the die temperature rise is accurate we can make the cooling area a variable and find what area is need to reach the observed temperature rise. For a current of 20 ma and temperature rise of 64° C. was Observed. When the model was evaluated using a square area that is 2.7 mm on a side, the calculated temperature rise was the same as that measured. This is shown in the graph shown in FIG. 16. Further more detailed calculations will be necessary to check this hypothesis, but it appears that if lamps are spaced at say twice this distance, the area would function normally.

When a 2 mil layer of phosphor-polymer composite is added above the chip that extends over the PET, the model predicts a 15° C. increase in the junction temperature. The temperature rise above ambient would be about 80° C. This result is shown in the FIG. 17.

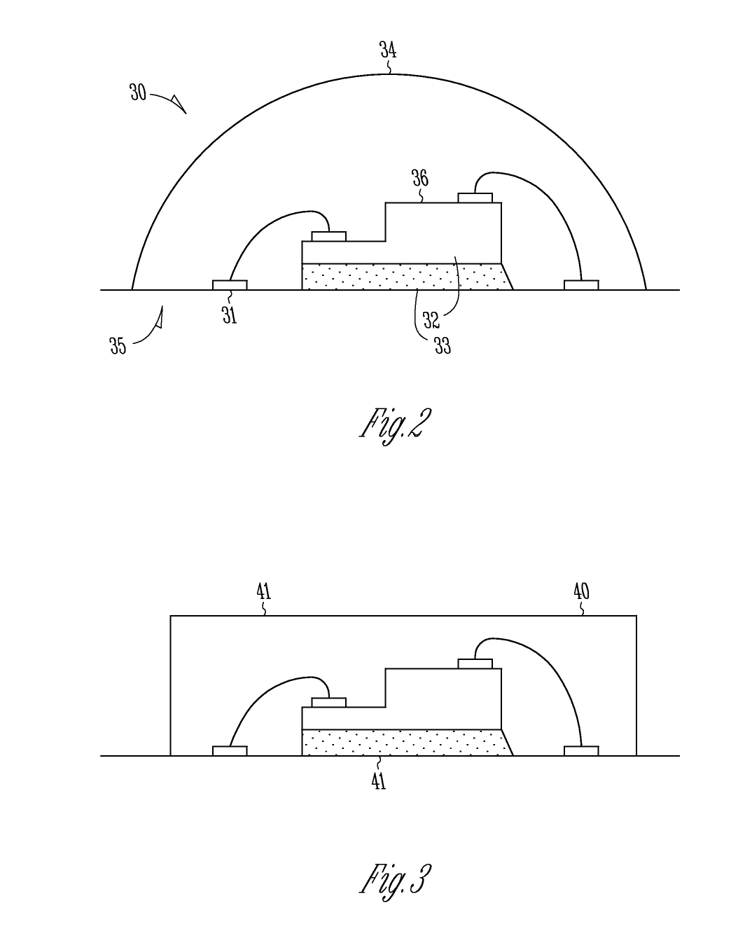

FIG. 2 is across-sectional view of a flexible transparent bare die LED circuit 30 with a flexible transparent substrate 31. The bare die LED circuit 30 includes a unit 35 having a transparent round GLOB-top 34 that is disposed over a bare die LED 32. The transparent round GLOB-top 34 provides protection for the bare die LEDs from atmospheric moisture and dust. For some embodiments, the transparent GLOB-top 34 includes one or more of an adhesive and a phosphor. The transparent GLOB-top is made of one or more of an epoxy, silicone, and polyimide polymer. The transparent GLOB-top has sufficient flexibility to move with the flexible transparent substrate 31, without forming cracks or other mechanical stresses, For some embodiments, the transparent GLOB-top 34 has a lens property that focuses the bare die LED light source. For other embodiments, the GLOB-top has a light diffusive property. These properties enhance the illumination of the bare die LED circuit 30.

The wire interconnect bonding disclosed herein fbr the embodiment in FIG. 1 is also usable for the embodiment illustrated in FIG. 2. The heat management separation between units 10 and 10’ disclosed herein is also applicable for embodiments having a GLOB-top.

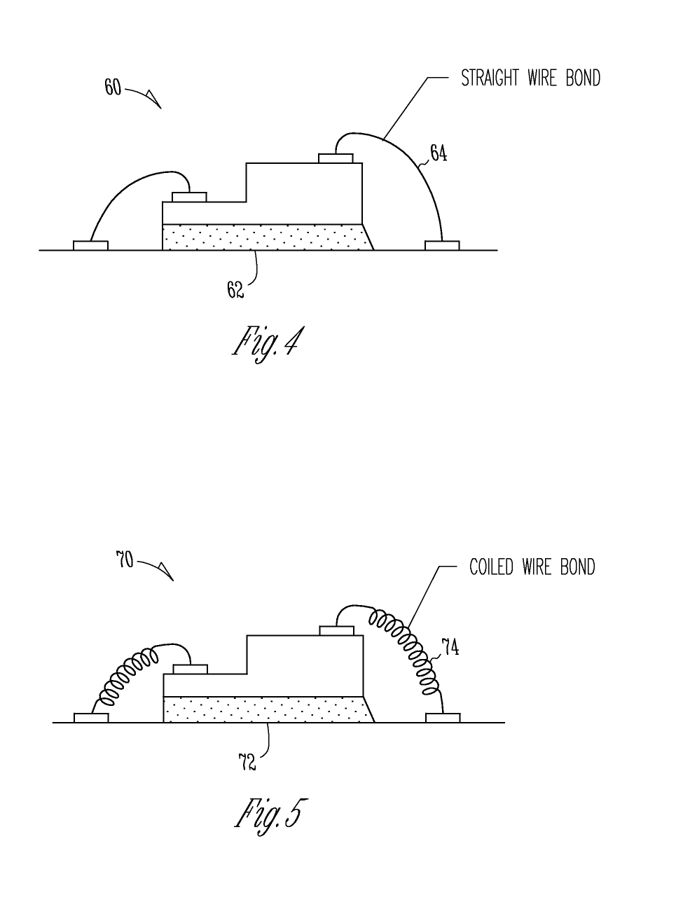

FIG. 3 illustrates aside view of a bare die LED circuit 41 having a flat GLOB-top 40. As discussed for the GLOB-top in HG. 2, the GLOB-top 40 provides protection for the bare die LED from atmospheric moisture and dust. For some embodiments, the GLOB-top 40 includes one or more of an adhesive and a phosphor. The GLOB-top 40 is made of one or more of an epoxy, silicone, and polyimide polymer. The GLOB-top has sufficient flexibility to move with the flexible substrate 41, without forming cracks or other mechanical stresses. For some embodiments, the GLOB-top 40 has a lens property that focuses the bare die LED light source. Furthermore, the GLOB-top 40 is resistant to fatigue failure due to flexing. The GLOB-top 40 and flexible transparent substrate 41 have substantially the same coefficient of thermal expansion. Thus, for some embodiments, the GLOB-top 40 and flexible transparent substrate 41 are both made of the same materials.

A circuit, such as circuit 35, is enclosed by the flexible transparent substrate 31 and the GLOB-top 34. The circuit 35 is attached to a power source, providing power to the bare die LED. Powering the bare die LEDs 36 may aid in curing the adhesive 33.

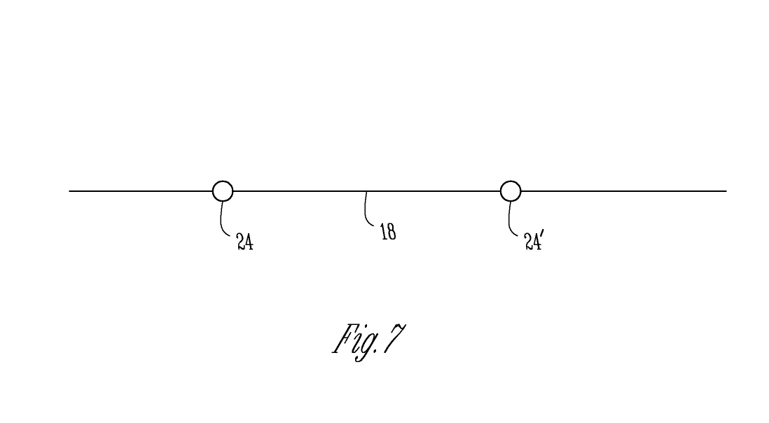

Particular wire interconnect embodiments are shown in FIGS. 4 and 5, FIG. 4 illustrates a circuit 60 with a bare die LED unit 62 having a straight wire bond 64. FIG. 5 illustrates a circuit 70 with a bare die LED unit 72 having a coiled wire interconnect bond 74. These embodiments may also include features disclosed herein for the enibodiment illustrated in FIG. 1.

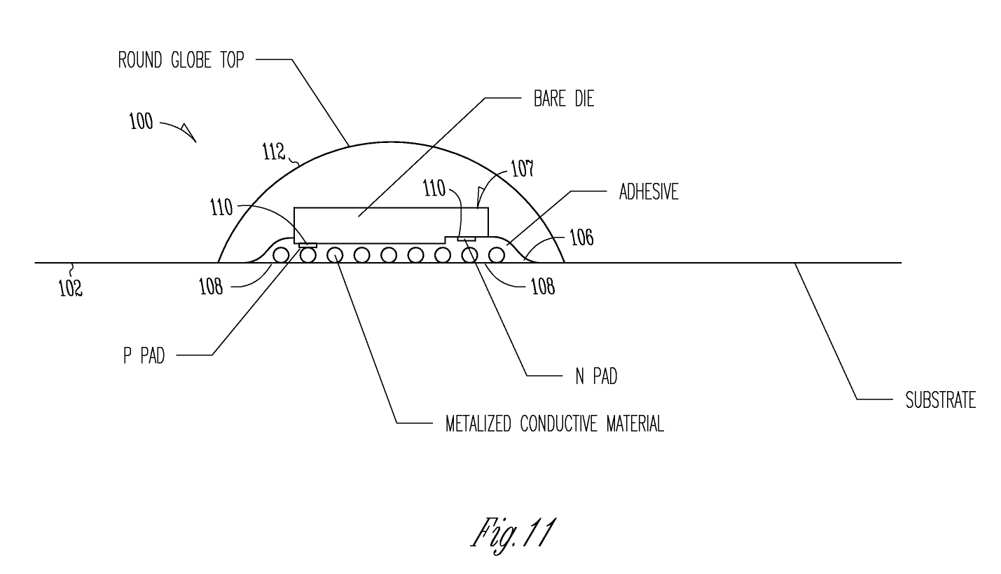

Another transparent flexible device embodiment is illustrated generally at 50 in FIG. 8. The device 50 includes a flexible transparent substrate 52 and an adhesive 54 adhered to the flexible transparent substrate 52, covering a portion of the substrate 52. Two or more bare die LEDs 56 and 56′ adhere to the adhesive 54, the two or more bare die LEDs 56 and 56′ spaced as little as 0.22 inches (5.4 mm), or less, apart. The embodiment 50 also includes a printed interconnect 58. The printed interconnect 58 terminates at each of a pair of conductive traces 60 and 60′ that include copper etched into the substrate 52 and positioned on opposing sides of the bare die LEDs 56 and 56′. The printed interconnect 58 also terminates at each of a pair of conductive pads 62 and 62′ that includes conductive print 64 adhered to the bare die LEDs and positioned on opposing surfaces of the bare die LEDs 56 and 56′. The conductive print 64 interconnects the traces 60 and 60′ and the pads 62 and 62,′ respectively. For some embodiments, the conductive ink is printed onto each of the pads 60 and 60′.

Another device embodiment that has a conductive printed interconnect is illustrated generally at 200 in FIG. 9. The embodiment 200 includes dies 202 and 202′ adhered to a substrate 204 with an adhesive 306. A printed interconnect is shown at 208. Inclusive with the interconnect is a trace and a pad. A round GLOB-top 210 is positioned over the dies 202 and 202′. The round GLOB-top may include embodiments such as those disclosed for the device having a wire interconnect.

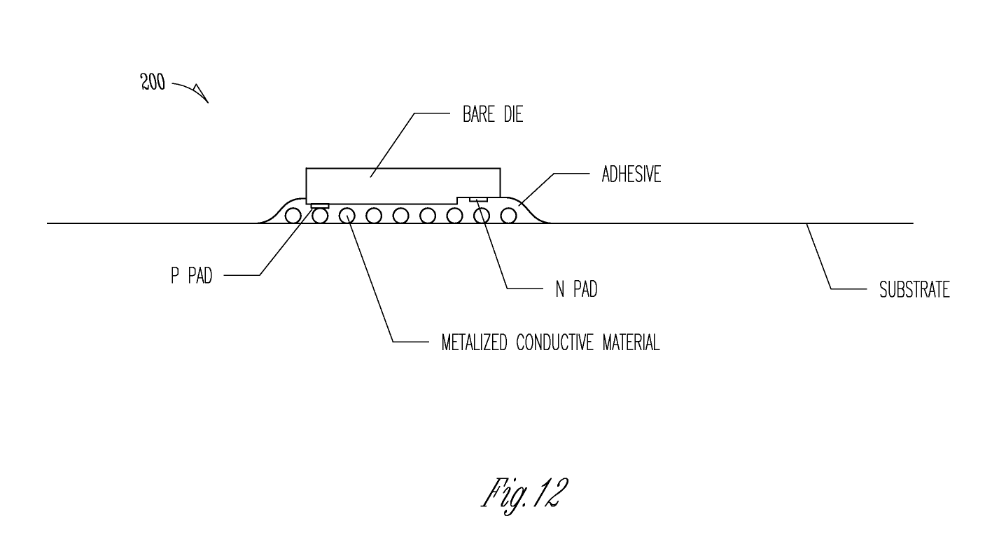

One other device embodiment that has a conductive printed interconnect is illustrated generally at 300 in FIG. 10. The device 300 includes the features disclosed for device 200 in FIG. 9 that are enclosed within a GLOB-top 302 having a square top. The square GLOB-top may include embodiments such as those disclosed fir the device having a wire interconnect. Both GLOB-top embodiments may include substrate, pad, circuit and heat management features that have been disclosed for embodiments employing a wire bond.

The printed interconnect 64 includes, for some embodiments, an ink print made by a material such as nanoparticle-ink, referred to herein as a “nanoink”. Nanoink includes nanoparticles and little or no polymeric binder. Nanoink relies on sintering to achieve mechanical integrity.

Ink print may also include one or more thick film inks that have conductive particles dispersed in a matrix of polymer binder, relying on particle-to-particle contact for electrical conductivity. The polymeric matrix imparts mechanical integrity.

Some printing method embodiments disclosed herein include printing a nanoink to make an interconnect and then overprinting the interconnect with a thick film conductive ink to bridge any microcracks that might develop in the nanoink from thermal or mechanical stresses. While thick film conductive inks are typically only one-fourth to one-tenth (or even less) conductive as nanoinks their flexibility and extensibility enables an overprint to bridge microcracks in the nanoink and thus maintain the electrical connection with very little added resistance to the circuit.

The metallic particles within the nation* are small enough to be aerosol jet printed and to retain flexibility when applied to the flexible transparent substrate 52. For some embodiments, the polymeric binder forms a film when the conductive ink is dried and fused. Conductive ink embodiments that include a polymeric binder are more robust than other conductive inks. For some embodiments, the polymeric binder has properties compatible with the properties of the transparent flexible substrate 52.

One other type of nanoparticle jet printing is a micro cold spray. Micro cold spray is applicable to flexible substrates without a need for post-processing, making it usable on low temperature substrates. The micro cold spray employs no solvents so features deposited to make an interconnect do not shrink. Micro cold spray allows a use of less expensive metal powders such as copper, aluminum, and tin to make conductive print interconnections. Micro cold spray is, for some embodiments, used to apply a metal such as copper to the surface of a substrate to form an electrical trace.

The conductive ink is, for some embodiments, silver. For some embodiments, the conductive ink includes copper. The conductive ink includes gold, for some embodiments. Each of these inks includes metal particles the size of nanoparticles. Consolidation of the nanoparticles to make a printed interconnect occurs by low temperature sintering. Consolidation occurs when there is particle-to-particle contact, such as when the solvent or a protective material surrounding the nanoparticles evaporates.

For some embodiments of the printed interconnect 58, conductive ink is printed in dots of ink. In other embodiments, the printed interconnect includes a continuous line of conductive ink made with a series of dots of conductive ink. The dots may be separated from each other prior to the ink being melted or fused.

After the conductive ink is printed on the bare die 56 or 56′ to make the printed interconnect traces 58 and 58′, the ink is fused. During the fusing stage, the dots of conductive ink are fused together. The dots of conductive ink lose their dot shape during the fusing process. For some embodiments, conductive ink is printed using a jet printer such as an aerosol jet printer or a three dimensional printer.

For some embodiments, aerosol jet printers usable herein include printers effective for printing in three dimensions. Printing with an aerosol jet printer creates a continuous line of conductive ink and prevents a gap in the conductive ink in the printed interconnection 58 and 58′.

Aerosol jet printers employ a variety of inks. For some embodiments, the aerosol jet printer embodiment makes a print interconnect that includes an ink having a distribution of particle sizes. In one embodiment, the ink includes particles having a size up to 0.5 μm. Other ink embodiments have a particle size smaller than 0.5 μm.

The conductive ink may be printed on one or more surfaces of a bare LED die 56, such as curved surfaces, irregular surfaces and non-continuous, surfaces. Conductive ink is also usable to make traces on a flexible substrate that is rolled or twisted.

The head of the printer is, for some embodiments, at an angle other than vertical, to encourage a continuous line of conductive ink A continuous line of conductive ink is formed by printing in three dimensions, to connect a line of conductive ink on the substrate 52 to a line of conductive ink on the top surface 57 of the bare LED die 56. Printing conductive ink in three dimensions includes printing on intersecting planes, for example via adjustment along, and/or printing onto x, y and z planes. Printing conductive ink in three dimensions includes printing on parallel planes. The angle of the aerosol jet printer head can be 45°. Other angles of the aerosol jet printer head are possible.

For some embodiments, the conductive ink is disposed in a continuous, monolithic path, to form a conductive printed interconnection. For some embodiments, the conductive ink is printed in dots. The conductive ink is, for some embodiments, heated, to melt the dots of conductive ink or fuse the dots of conductive ink, so that the dots of conductive ink become electrically conductive with one another. The dots are melted or fused to form a conductive unit of conductive ink.

As disclosed in US Patent application, 2012/0175667A1, it is demonstrated that some bare die LED chip architectures require that an insulating layer be printed between doped layers or the formation of a Schottky diode, either of which can cause a bare die LED not to light. Examples of suitable insulators include Luvitec PVP, available from Aldrich Chemical and poly (methyl methacrylate) resin (PMMA) available from BASF.

One other bare die LED circuit embodiment employing a magnetically aligned anisotropic conductive material (MACM) embodiment is illustrated generally at 100 in FIG. 11. The circuit 100 includes a flexible transparent substrate 102, a bare die LED 104, and a MACM interconnect 106. The MACM interconnect 106 conductively connects traces 108 in the substrate 102 and pads 110 in the bare die LED 104. Conductive particles in the MACM are able to accommodate any differences in height between the contact pads of an LED. MACM adhesives based on nanoparticles in particular are able to provide high connection densities that yield low contact resistance and high current carrying capability. Traditional anisotropic conductive materials (ACM) contain conductive particles (usually spheres) of relatively uniform size dispersed uniformly in an adhesive. Pressure is applied, sometimes along with heat, to make an electrical connection between two contact pads through the conductive particles. The adhesive is then cured with heat or UV exposure or cooled in the case of a thermoplastic adhesive to solidify and stabilize the connection. MACMs, magnetic anisotropic conductive materials, typically contain ferromagnetic particles randomly dispersed in a resin. An externally applied magnetic field can force these particles to align. If the spacing between contact pads is greater than the particle size, several particles can link together in alignment between contact pads to form an electrical connection. By controlling contact pad size, spacing concentration of conductive particles, and the size and shape of the conductive particles, a sufficient number of connections can be made to ensure adequate current carrying capacity for the application. Both traditional anisotropic conductive materials and magnetically aligned anisotropic conductive materials with resin binder are readily commercially available as adhesives, pastes, and films.

Cationic cured adhesive binders are particularly useful Cationic UV adhesive or Dark curing adhesive needs no exogenous source of heat to cure. Only a small portion of the adhesive needs to be exposed to UV rays to start the initial curing process. The curing process continues until the entire adhesive is fully cured. This allows the curing of adhesive that is under a component that is not visible to any UV light or the dark area. No heat is needed for the curing process. The use of these materials is well-understood by those of ordinary skill in the art,

Epoxides have wide use in the area of cationic UV-curable adhesives. Three types of epoxides having wide use include glycidyl ether, epoxidized seed oil, soybean or linseed oil, and cycloaliphatic epoxide. The cycloaliphatic epoxide has the fastest cure response, strong adhesion to a wide variety of substrates and good electrical properties. Cross-linkers such as di and tri polyols are typically added to improve toughness. The term, “dark cure”, as used herein, refers to a propagation of cationic UV-curable coatings after UV-exposure.

Suitable photoinitiators for the cationic UV curing of a cycloaliphatic epoxide include onimum salts that undergo photodecomposition to yield onimum salts that photodecompose to yield a cationic species for initiation and propagation of the polymerization. One salt is sulfonium salt. Another is photogenerated HPF(6). Other photoinitiators known to those of ordinal); skill in the art are also suitable for use.

The cationic UV-curable adhesive embodiments are effective to receive magnetic particles over a wide range of loading. For some embodiments, the particles are magnetic nanoparticles. The magnetic particles, including nanoparticles, may be ferromagnetic particles. The ferromagnetic particles are added to the UV-curable adhesive. The cationic UV-curable adhesive with magnetic particles is applied to a desired surface where the magnetic particles are arranged in a magnetic field. The magnetic particles, including nanoparticles are arranged so that an electrical connection is made in the Z-axis. The cationic UV-curable adhesive with magnetic particles is then subjected to an ultraviolet energy source of 380 nm for a period of eight seconds, for some embodiments. It is possible to cure the adhesive in as little as three seconds. The adhesive is cured without being subjected to a separate heating step.

Modifiers are, for some embodiments, added to impart a desired flexibility and adhesion to the UV-curable adhesive.

Another bare die LED circuit embodiment, illustrated at 200 in FIG. 12, illustrates the circuit 200 that does not include a Gt0B4op, One other bare die LED circuit embodiment, illustrated at 300 in FIG. 13 illustrates the circuit 300, enclosed in a flat GLOB-top 202. Each of the embodiments 200 and 300 includes a substrate, bare die LEDs and MACM interconnect as is disclosed for embodiment 100.

Inventive aspects disclosed herein include a flexible device such as has been disclosed for a wire interconnect, a conductive print interconnect and a. MACM interconnect. The flexible device includes a flexible transparent substrate and an adhesive adhered to the flexible transparent substrate, covering a portion of the substrate. The device also includes two or more bare die LEDs adhered to the adhesive, the two or more bare die LEDs spaced as little as 0.22 inches (5.4 mm), or less, apart. The device additionally includes a pair of conductive traces on or in the substrate and positioned on opposing sides of the bare die LEDs; a pair of conductive pads positioned on opposing surfaces of the bare die LEDs; and an interconnect that interconnects the pads and the traces.

For some applications, the use of circuitry based on metalized flexible substrates is advantageous. Circuits formed on flexible substrates can include metalized film with a circuit patterned by masking, preprinted image masks, laser ablation other high intensity electromagnetic radiation exposure, or mechanical or chemical etching. The metalized circuitry remaining can optionally be rendered more conductive by plating additional material onto the circuitry. Bare die LEDs are attached to this circuitry using printed, wire bonded, conductive adhesive, or MACM interconnects. For some embodiments, a flexible polymeric substrate is overlayed with a metalized film. The some embodiments, the metalized substrate or film is light reflective.

The embodiments disclosed herein may be manufactured using roll-to-roll processing, which allows for continuous production, significant increase in throughput and a reduction in capital cost and device cost.

The above detailed description includes references to the accompanying drawings, which form a part of the detailed description. The drawings show, by way of illustration, specific embodiments in which the invention can be practiced. These embodiments are also referred to herein as “examples.” Such examples can include elements in addition to those shown or described. However, the present inventors also contemplate examples in which only those elements shown or described are provided. Moreover, the present inventors also contemplate examples using any combination or permutation of those elements shown or described (or one or more aspects thereof), either with respect to a particular example (or one or more aspects thereof), or with respect to other examples (or one or more aspects thereof) shown or described herein,

In the event of inconsistent usages between this document and any documents so incorporated by reference, the usage in this document controls.

As used herein, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In this document, the terms “including” and “in which” are used as the plain-English equivalents of the respective terms “comprising” and “wherein.” Also, in the following claims, the terms “including” and “comprising” are open-ended, that is, a system, device, article, composition, formulation, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

Method examples described herein can be machine or computer-implemented at least in part. Some examples can include a computer-readable medium or machine-readable medium encoded with instructions operable to configure an electronic device to perform methods as described in the above examples. An implementation of such methods can include code, such as microcode, assembly language code, a higher-level language code, or the like. Such code can include computer readable instructions for performing various methods. The code may form portions of computer program products. Further, in an example, the code can be tangibly stored on one or more volatile, non-transitory, or non-volatile tangible computer-readable media, such as during execution or at other times. Examples of these tangible computer-readable media can include, but are not limited to, hard disks, removable magnetic disks, removable optical disks (e.g., compact disks and digital video disks), magnetic cassettes, memory cards or sticks, random access memories (RAMs), read only memories (ROMs), and the like.

The above description is intended to be illustrative, and not restrictive. For example, the above-described examples (or one or more aspects thereof) may be used in combination with each other. Other embodiments can be used, such as by one of ordinary skill in the art upon reviewing the above description. The Abstract is provided to comply with 37 C.F.R. §1.72(b), to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description as examples or embodiments, with each claim standing on its own as a separate embodiment, and it is contemplated that such embodiments can be combined with each other in various combinations or permutations. The scope of the invention should be determined with reference to the appended claims, along with the full scope of equivalents to which such claims are entitled.

What is claimed is:

1. A flexible device, comprising:
a flexible transparent substrate;
an adhesive adhered to the flexible transparent substrate, covering a portion of the substrate;
two or more bare die LEDs adhered to the adhesive, the two or more bare die LEDs spaced as little as 0.22 inches (5.4 mm), or less, apart; and
an interconnect, comprising:
a pair of conductive traces adhered or etched to the substrate and positioned on opposing sides of the bare die LEDs;
a pair of conductive pads adhered to the bare die LEDs and positioned on opposing surfaces of the bare die LEDs; and
an interconnect comprising a pair of wires, each wire bonded to a trace and a pad to form a wire bond.

2. The flexible device of claim 1, wherein the two or more bare die LEDs adhered to the flexible transparent substrate comprise wires bonded to each of a pad and a trace.

3. The flexible device of claim 2, wherein the transparent flexible substrate is effective for omnidirectionally illuminating a space at similar intensity because light from the bare die LEDs passes through the transparent flexible substrate.

4. The flexible device of claim 1, further comprising a round GLOB-top that encloses the bonded wires, bare die LED, and adhesive.

5. The flexible device of claim 1, further comprising a flat GLOB-top that encloses the bonded wires, bare die LEDs and adhesive.

6. The flexible device of claim 1, wherein the wires of the wire bonds are coiled.

7. The flexible device of claim 1, wherein the conductive print of the trace comprises silver distributed over the surface of the substrate as nanoparticles.

8. The flexible device of claim 1, wherein the conductive print of the trace comprises gold, distributed over the surface of the substrate as sintered nanoparticles.

9. The flexible device of claim 3, wherein the GLOB-top and flexible substrate have substantially the same coefficient of expansion.

10. The flexible device of claim 3, wherein the GLOB-top and flexible substrate are made of the same material.

11. The flexible device of claim 1, wherein the trace has a flexibility compatible with the flexibility of the substrate.

12. The flexible device of claim 1, wherein the bare die LEDs have flexibility.

13. A flexible device, comprising:
a flexible transparent substrate;
an adhesive adhered to the flexible transparent substrate, covering a portion of the substrate;
two or more bare die LEDs adhered to the adhesive, the two or more bare die LEDs spaced as little as 0.22 inches (5.4 mm), or less, apart;
a pair of conductive traces adhered or etched on or in the substrate and positioned on opposing sides of the bare die LEDs;
a pair of conductive pads positioned on opposing surfaces of the bare LED die; and
an interconnect comprising a magnetically aligned anisotropic conductive material having elements that have been aligned magnetically that interconnects the pads and the traces.

14. The flexible device of claim 13, wherein the substrate comprises a magnetically aligned anisotropic conductive material having elements that have been aligned magnetically.

15. The flexible device of claim 13, wherein the magnetically aligned anisotropic conductive material comprises magnetic nanoparticles.

16. A flexible device, comprising:
a flexible transparent substrate;
an adhesive adhered to the flexible transparent substrate, covering a portion of the substrate;
two or more bare die LEDs adhered to the adhesive, the two or more bare die LEDs spaced as little as 0.22 inches (5.4 mm), or less, apart;
a pair of conductive traces adhered or etched on or in the substrate and positioned on opposing sides of the bare die LEDs;
a pair of conductive pads positioned on opposing surfaces of the bare LED die; and
an interconnect comprising a cationic UV curable adhesive with magnetic nanoparticles within the adhesive, that have been aligned magnetically, the interconnect interconnecting the pads and the traces.

17. The flexible device of claim 16, wherein the magnetic nanoparticles within the UV curable adhesive have a distribution effective for making an electrical connection in the Z-axis.

18. A flexible device, comprising:
a flexible substrate, comprising a metalized film and one or more circuits on and within the metalized film;
an adhesive adhered to the flexible substrate, covering a portion of the substrate;
two or more bare die LEDs adhered to the adhesive, attached to the one or more circuits, the two or more bare die LEDs spaced as little as 0.22 inches (5.4 mm), or less, apart; and
an interconnect, comprising:
a pair of conductive traces adhered or etched to the substrate and positioned on opposing sides of the bare die LEDs;
a pair of conductive pads adhered to the bare die LEDs and positioned on opposing surfaces of the bare die LEDs; and
an interconnect comprising a pair of wires, each wire bonded to a trace and a pad to form a wire bond.
